(19) United States
(12) Patent Application Publication
(10) Pub. No.: US 2020/0119236 A1
(43) Pub. Date: Apr. 16, 2020

(54) DISPLAY UNIT, DISPLAY SUBSTRATE AND METHOD OF MANUFACTURING THE SAME, DISPLAY DEVICE

(71) Applicants: BEIJING BOE DISPLAY TECHNOLOGY CO., LTD., Beijing (CN); BOE TECHNOLOGY GROUP CO., LTD., Beijing (CN)

(72) Inventors: Bingqing YANG, Beijing (CN); Wenkai MU, Beijing (CN); Bo FENG, Beijing (CN); Ji DONG, Beijing (CN); Haoliang JI, Beijing (CN); Shijun WANG, Beijing (CN); Xiaoxiao CHEN, Beijing (CN); Wenjun XIAO, Beijing (CN)

(21) Appl. No.: 16/451,331

(22) Filed: Jun. 25, 2019

(30) Foreign Application Priority Data
Oct. 12, 2018 (CN) 201811191001.3

(51) Int. Cl. H01L 33/50; H01L 25/075; H01L 27/12; H01L 33/58

(52) U.S. Cl. CPC H01L 33/505; H01L 25/0753; H01L 2933/0058; H01L 33/58; H01L 2933/0041; H01L 27/1214

(57) ABSTRACT

A display unit, a display substrate and a method of manufacturing the same and a display device. The display unit includes: a Micro-LED chip arranged on a base substrate and a color filter. The Micro-LED chip is configured for emitting light in a first color. The color filter is arranged on the Micro-LED chip, configured for packaging the Micro-LED chip and converting the light in the first color into an outgoing light in a second color, and includes a convex structure in a light outgoing path of the Micro-LED chip.

### CROSS-REFERENCE TO RELATED APPLICATION

The present application claims priority to Chinese Patent Application No. 201811191001.3, filed on Oct. 12, 2018, the disclosure of which is incorporated herein by reference in its entirety as part of the present application.

### TECHNICAL FIELD

Embodiments of the present disclosure relate to a display unit, a display substrate and a method of manufacturing the same, and a display device.

### BACKGROUND

With the rapid development of a wearable display device, micro light emitting diode (Micro-LED, pLED) technology is emerging. The Micro-LED technology (including LED miniaturizing and matrixing technologies) refers to integration of a high-density miniaturized LED array on a chip. A Micro-LED display has a power consumption much less than a liquid crystal display (LCD), and is also self-luminous, like an organic light-emitting diode (OLED) display. It is possible for a Micro-LED display to reduce the magnitude of a distance between pixels from millimeter to micron, the color saturation of the Micro-LED display is close to that of an OLED display, and thus the Micro-LED display is deemed as the next generation of display technology by many manufacturers. The inorganic material-based Micro-LED has the advantages of self-luminous characteristics, a small size, a light weight, a high brightness, a longer service life, lower power consumption, shorter response time and higher controllability, and the Micro-LED technology is to realize the thin film, miniaturization and array design of the structure of LEDs.

### SUMMARY

At least one embodiment of the present disclosure provides a display unit, which includes:

a micro light emitting diode (Micro-LED) chip, arranged on a base substrate and configured for emitting light in a first color; and

a color filter, the color filter being arranged on the Micro-LED chip, the color filter being configured for packaging the Micro-LED chip and converting the light in the first color into an outgoing light in a second color, and the color filter comprising a convex structure in a light outgoing path of the Micro-LED chip.

In the display unit according to some embodiments of the present disclosure, the convex structure is a convex lens structure.

In the display unit according to some embodiments of the present disclosure, the Micro-LED chip is at a focal point of the convex lens, so as to convert the light in the first color emitted from the Micro-LED chip into the outgoing light in the second color, and the outgoing light in the second color is substantially parallel.

In the display unit according to some embodiments of the present disclosure, a distance from the micro-LED chip to an optical center of the convex lens is less than a focal length of the convex lens.

In the display unit according to some embodiments of the present disclosure, in at least one direction, the Micro-LED chip has a dimension in a range of 1 micron˜10 microns.

In the display unit according to some embodiments of the present disclosure, the first color is white, and the second color is one selected from a group consisting of red, blue and green.

At least one embodiment of the present disclosure provides a display substrate, which includes:

a base substrate; and

a plurality of the above-mentioned display units, arranged on the base substrate in an array,

wherein the plurality of display units are divided into a plurality of subarrays, each of plurality of subarrays comprises a first display unit, a second display unit and a third display unit, the first display unit, the second display unit and the third display unit emit outgoing light in different colors.

In the display substrate according to some embodiments of the present disclosure, in each of the plurality of subarrays, each of the first display unit, the second display unit and the third display unit is arranged adjacent to a different type of display unit in each of a row direction and a column direction.

In the display substrate according to some embodiments of the present disclosure, each of the first display unit, the second display unit and the third display unit of each of the plurality of subarrays is arranged adjacent to a different type of display unit of an adjacent subarray in each of the row direction and the column direction.

In the display substrate according to some embodiments of the present disclosure, the outgoing light emitted from each of the first display unit, the second display unit and the third display unit has a color of one selected from a group consisting of red, green and blue, and the outgoing light emitted from the first display unit, the second display unit and the third display unit has different colors.

In the display substrate according to some embodiments of the present disclosure, each of the plurality of subarrays comprises:

the first display unit, the second display unit and the third display unit arranged in sequence in a first direction in a first row;

the second display unit, the third display unit and the first display unit arranged in sequence in the first direction in a second row; and

the third display unit, the first display unit and the second display unit arranged in sequence in the first direction in a third row,

wherein the first display unit emits red outgoing light, the second display unit emits green outgoing light, and the third display unit emits blue outgoing light.

The display substrate according to some embodiments of the present disclosure further comprises a light blocking layer, wherein the light blocking layer is on the base substrate and between adjacent display units.

At least one embodiment of the present disclosure provides a display device, which includes the above-mentioned display substrate.

At least one embodiment of the present disclosure provides a method of manufacturing the above-mentioned display substrate, which includes:

transferring a plurality of Micro-LED chips in an identical color onto the base substrate; and

arranging a plurality of color filters on the base substrate, wherein each of the plurality of color filters covers and packages at least one of the plurality of Micro-LED chips to obtain the display substrate.

### BRIEF DESCRIPTION OF THE DRAWINGS

In order to clearly illustrate the technical solution of the embodiments of the present disclosure, the drawings of the embodiments will be briefly described in the following; it is obvious that the described drawings are only related to some embodiments of the present disclosure and thus are not limitative of the present disclosure.

FIG. 1 is a schematic structural diagram of a display unit according to some embodiments of the present disclosure.

FIG. 2 is a schematic structural diagram of a display unit according to some embodiments of the present disclosure.

FIG. 3 is a schematic top view of a display substrate according to some embodiments of the present disclosure.

FIG. 4 is a sectional view along line A-A′ in FIG. 3.

FIG. 5 is a schematic block diagram of a display device according to some embodiments of the present disclosure.

FIG. 6 is a flow chart of a method of manufacturing a display substrate according to some embodiments of the present disclosure.

### DETAILED DESCRIPTION

In order to make objects, technical details and advantages of the embodiments of the present disclosure apparent, the technical solutions of the embodiments will be described in a clearly and fully understandable way in connection with the drawings related to the embodiments of the present disclosure. Apparently, the described embodiments are just a part but not all of the embodiments of the present disclosure. Based on the described embodiments herein, those skilled in the art can obtain other embodiment(s), without any inventive work, which should be within the scope of the present disclosure.

Unless otherwise defined, all the technical and scientific terms used herein have the same meanings as commonly understood by one of ordinary skill in the art to which the present disclosure belongs. The terms “first,” “second,” etc., which are used in the description and the claims of the present application for invention, are not intended to indicate any sequence, amount or importance, but distinguish various components. Also, the terms such as “a,” “an,” etc., are not intended to limit the amount, but indicate the existence of at least one. The terms “comprise,” “comprising,” “include,” “including,” etc., are intended to specify that the elements or the objects stated before these terms encompass the elements or the objects and equivalents thereof listed after these terms, but do not preclude the other elements or objects. The phrases “connect”, “connected”, etc., are not intended to define a physical connection or mechanical connection, but may include an electrical connection, directly or indirectly. “On,” “under,” “right,” “left” and the like are only used to indicate relative position relationship, and when the position of the object which is described is changed, the relative position relationship may be changed accordingly.

In order to keep the following description of the embodiments of the present disclosure clear and concise, detailed descriptions of known functions and known components are omitted in the present disclosure.

Usually, a Micro-LED display module is formed by transferring the Micro-LEDs in batches onto a circuit substrate, then making a protective layer and an electrode and finally performing packaging. A single Micro-LED is usually monochromatic. If the Micro-LED display module is desired to emit colored light, the Micro-LEDs in different colors are required to be transferred in batches onto the circuit substrate for many times to obtain a display array. However, the above-mentioned transferring technology is difficult, and a mounting accuracy is difficult to control, which causes a low product yield and fails to realize real volume production.

On the other hand, due to its small size, the Micro-LED may realize a high PPI display device, and thus may be applied to scenarios such as virtual display glasses, large screen projection, or the like. These applications have higher demands for display effects of the Micro-LED device, and a problem of visual graininess at the edge due to a pixel arrangement will be serious.

At least one embodiment of the present disclosure provides a display unit, including a base substrate, a Micro-LED chip and a color filter. The Micro-LED chip is arranged on the base substrate, and configured for emitting light in a first color. The color filter is arranged on the Micro-LED chip, is configured for packaging this Micro-LED chip and converting the light in a first color into an outgoing light in a second color, and includes a convex structure located in a light outgoing path of the Micro-LED chip.

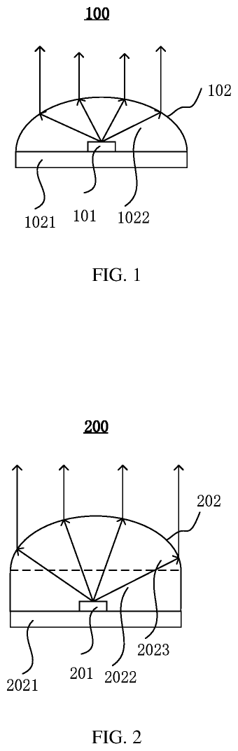

FIG. 1 is a schematic structural diagram of a display unit 100 according to some embodiments of the present disclosure. As shown in FIG. 1, the display unit 100 includes a Micro-LED chip 101 and a color filter 102 arranged on the base substrate 1021.

For example, the Micro-LED chip 101 includes an unpackaged chip or a bare chip which is partially packaged or bonded, and may emit light in a first color in case of being provided with power. For example, the Micro-LED chip 101 is obtained by being manufactured on a supply base (for example, a sapphire base) through a semiconductor process, being cut and separated from this supply base, and the embodiments of the present disclosure have no limitation on the manufacturing material, process and structure of the Micro-LED chip. In some embodiments, this first color is white. In some other embodiments, this first color is blue, red, green, or the like.

The color filter 102 is arranged on the Micro-LED chip 101. In some embodiments, the color filter 102 may cover the whole Micro-LED chip 101. The color filter 102 is configured for packaging the Micro-LED chip 101, i.e., sealing the Micro-LED chip 101 to prevent the Micro-LED chip 101 from being exposed to an external environment, prevent water vapor or oxygen gas in the air from entering or penetrating the display unit 100, thereby avoiding adverse influences on the performance of the Micro-LED chip 101, and eliminating the need of a separate package or seal structure. In addition, the color filter 102 has a color filtering function, and is further configured for converting the light in the first color emitted from the Micro-LED chip 101 into the outgoing light in the second color. For example, the second color may be red, blue, green, or the like. In the embodiments of the present disclosure, the color filter 102 not only packages the Micro-LED chip 101, but also enables the display unit 101 to emit the light in a desired color, thereby achieving, for example, displaying color.

For example, in an embodiment of the present disclosure, the Micro-LED chip 101 may emit white light, and the color filter 102 may convert the white light emitted from the Micro-LED chip 101 into red, blue or green light, thereby emitting red, blue or green outgoing light through the Micro-LED chip which emits white light.

In some embodiments of the present disclosure, the color filter 102 may include a convex structure which is convex away from the Micro-LED chip 101. The convex structure may have any shapes, for example, hemisphere, polyhedron, or the like. In some embodiments of the present disclosure, the convex structure is a convex lens structure, thereby obtaining a microlens corresponding to the Micro-LED chip 101. For example, in FIG. 1, the color filter 102 is entirely shown having a planoconvex lens structure.

FIG. 2 is a schematic structural diagram of a display unit 200 according to some other embodiments of the present disclosure. As shown in FIG. 2, the display unit 200 includes a Micro-LED chip 201 and a color filter 202 arranged on a base substrate 2021, and the color filter 202 has a structure in which the planoconvex lens is combined with a columnar part (such as a cylinder, a square column, or the like). Although it is shown in FIGS. 1 and 2 that a part of the color filter has a planoconvex lens structure, persons skilled in the art should understand that the color filter may have a convex lens structure in other forms, such as a meniscus lens, and the embodiments of the present disclosure are not limited thereto.

In the embodiments as shown in FIG. 1, the color filter 102 may include a convex portion 1022. The convex portion 1022 is an example of the above-mentioned convex structure. The convex portion 1022 may be arranged on the base substrate 1021 through pressing, photoetching, or the like, and may be of the above-mentioned second color, such as red, blue, green, or the like. The convex portion 1022 is located in a light outgoing path of the Micro-LED chip 101, and the light in the first color emitted from the Micro-LED chip 101 may be converted into light in the second color after passing through the convex portion 1022. The convex portion 1022 may be made of various appropriate materials, such as glass, resin, photoresist which is at least partially transparent, or the like. In some embodiments, the convex portion 1022 may be made of entirely transparent photoresist.

In the embodiments as shown in FIG. 2, the color filter 202 may include a base 2022 and a convex portion 2023. The convex portion 2023 is an example of the above-mentioned convex structure. The base 2022 and the convex portion 2023 may be arranged on the base substrate 2021 through pressing, photoetching, or the like, and one of the base 2022 and the convex portion 2023 may be of the above-mentioned second color, such as red, blue, green, or the like. The light in the first color emitted from the Micro-LED chip 201 may be converted into light in the second color after passing through the color filter 202. The convex portion 2023 is formed on the base 2022, for example, the convex portion 2023 may be integrally formed with the base 2022, or the convex portion 2023 and the base 2022 may be separately formed. In some embodiments, the base 2022 may be made of glass, resin, photoresist, or the like. For example, the convex portion 2023 may be obtained by coating the photoresist which is at least partially transparent on the base 2022 and exposing, developing the photoresist through a semi-transparent mask. In some embodiments, the convex portion 2023 may be made of entirely transparent photoresist. As mentioned above, the base 2022 and the convex portion 2023 may be made of different materials. However, persons skilled in the art should understand that the base 2022 and the convex portion 2023 may also be made of the same material. For example, the base 2022 and the convex portion 2023 may both be made of glass, resin, or photoresist which is at least partially transparent, and the embodiments of the present disclosure are not limited thereto.

As shown in FIGS. 1 and 2, a part (such as the convex portion) of the color filter may have a planoconvex lens structure. The relation between a curvature radius and a focal length of the planoconvex lens is as follows:

r=f*(n−1)

where r is a curvature radius of the planoconvex lens, f is a focal length of the planoconvex lens, and n is a refractive index of the planoconvex lens.

In some embodiments, when the Micro-LED chip is located at a focal point of the convex lens, more specifically, a light outgoing position of the Micro-LED chip is located at the focal point of the convex lens, the color filter may convert the light emitted from the Micro-LED chip into parallel light, i.e., the color filter has a collimation function. In the present disclosure, the parallel light may refer to collimated light. In some other embodiments, when a distance from the Micro-LED chip to an optical center of the convex lens is less than a focal length of the convex lens, more specifically, a distance from a light outgoing position of the Micro-LED chip to the optical center of the convex lens is less than the focal length of the convex lens, the color filter may further have a function of diverging light. In different applications, based on actual requirements, the convex portion of the color filter may have different curvature radii so that the color filter implements different functions.

In the embodiments of the present disclosure, how to determine the curvature radius of the convex portion of the color filter is explained by taking the planoconvex lens as an example. In the case where the convex portion of the color filter has other lens structures, the curvature radius of the convex portion of the color filter may be determined based on the specific lens structure.

For another example, in addition to the convex portion, the color filter may further include a color layer configured for achieving the color filtering function. This color layer may be arranged in a light emitting path of the Micro-LED chip, for example, at an upper surface of the convex portion, or between the base and convex portion, or the like, and the embodiments of the present disclosure are not limited thereto. Additionally, as mentioned above, the color filter may not include a separately provided color layer. In this case, the convex portion and/or the base of the color filter may have the function of filtering color, for example, a color converting material is mixed in the convex portion and/or the base.

In the display unit according to some embodiments of the present disclosure, the color filter converts the light emitted from the Micro-LED chip into substantially parallel outgoing light or divergent outgoing light. Therefore, when the display unit is in use, an extra light collimating device or light diverging device is no longer required to be arranged in the light outgoing path of the display unit.

The Micro-LED chip according to the present disclosure has a dimension of 1 micron˜10 microns in at least one direction. For example, the Micro-LED chip has a dimension of 1 micron, 5 microns, 10 microns, or the like in at least one direction. In addition, persons skilled in the art should understand that the display unit according to the embodiments of the present disclosure may include more Micro-LED chips, such as 2, 3, 4 or the like.

The display unit according to embodiments of the present disclosure may achieve displaying color, and may provide parallel light to reduce light loss or provide divergent light to implement magnification.

Some embodiments of the present disclosure further provide a display substrate which is provided with a plurality of mentioned-above display units arranged in an array. The plurality of display units are divided into a plurality of subarrays, each of which at least includes a first display unit and a second display unit which emit outgoing light in different colors. For example, the first and second display units are arranged adjacent to different types of display units in row and column directions.

As an example, the description will be made below by taking the subarray which includes three display units emitting outgoing light in three different colors as an example.

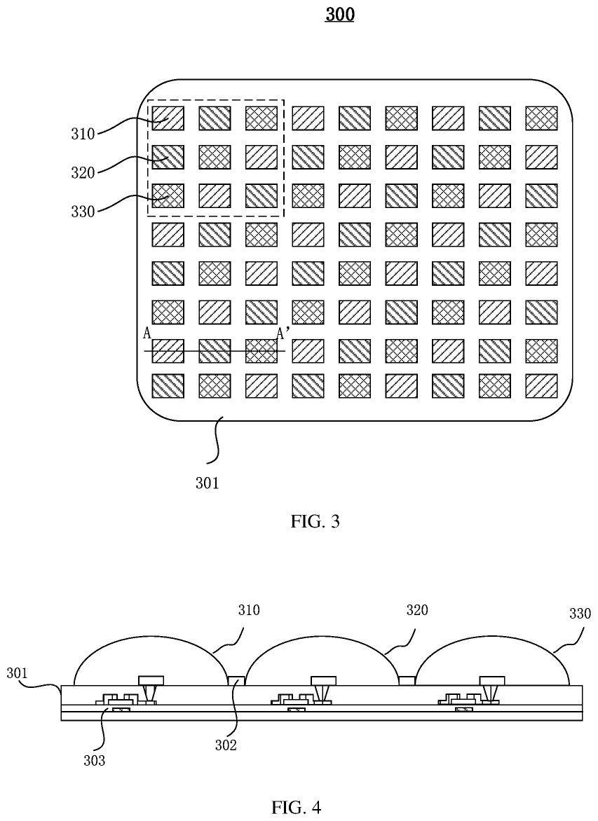

FIG. 3 is a schematic top view of a display substrate 300 according to some embodiments of the present disclosure. As shown in FIG. 3, the display substrate 300 includes a base substrate 301 and a plurality of the mentioned-above display units according to any one of the embodiments of the present disclosure which are arranged on the base substrate 301 in an array. The plural display units are divided into a plurality of subarrays (one of the subarrays is shown in a dotted block in FIG. 3).

In the embodiment shown in FIG. 3, each subarray includes a first display unit 310, a second display unit 320 and a third display unit 330, and in each subarray, the first, second, and third display units 310, 320 and 330 each are arranged adjacent to different types of display units in each of the row and column directions.

The first, second, and third display units 310, 320 and 330 emit outgoing light in different colors. As an example, the first display unit 310 may emit red light, the second display unit 320 may emit green light, the third display unit 330 may emit blue light, and persons skilled in the art should understand that the present disclosure is not limited thereto. For example, the first display unit 310 may also emit blue or green light, the second display unit 320 may also emit red or blue light, and the third display unit 330 may emit red or green light.

In addition, although FIG. 3 shows that each subarray includes three display units, persons skilled in the art should understand that based on actual requirements, each subarray may further include display units which may emit outgoing light in more colors or less colors. For example, in some embodiments, each subarray may include two display units emitting outgoing light in two colors, or four display units emitting outgoing light in four colors, and the embodiments of the present disclosure are not limited thereto. For example, the four colors of the outgoing light may include red, green, blue and yellow (RGBY), wherein the display unit which emits yellow light includes a yellow color filter, or the four colors of the outgoing light may include includes red, green, blue and white (RGBW), wherein the display unit which emits white light does not include a color filter.

As shown in FIG. 3, in some embodiments of the present disclosure, each subarrays has three rows and three columns, and each row and column of each subarray only includes one first display unit 310, one second display unit 320 and one third display unit 330. In the case where the subarray includes more or less types of display units, the subarray has more or less rows and columns. For example, in the case where the subarray includes two display units which emit outgoing light in two different colors, the subarray may have two rows and two columns; in the case where the subarray includes four display units which emit outgoing light in four different colors, the subarray may have four rows and four columns

The above-mentioned subarray is arranged repeatedly so that the first, second and third display units 310, 320 and 330 of each subarray are arranged adjacent to different types of display units of adjacent subarrays in row and column directions. As shown in FIG. 3, in the subarray shown by a dotted block, the second display unit 320 in the third row and the third column is adjacent to the third display units 330 of adjacent subarrays in the row and column directions. Since the first, second and third display units 310, 320 and 330 emit light in three colors, the three colors may be distributed evenly on the display substrate by the above-mentioned arrangement.

As shown in FIG. 3, in the first row of each subarray, the first, second and third display units 310, 320 and 330 are arranged in sequence from left to right; in the second row of each subarray, the second, third and first display units 320, 330 and 310 are arranged in sequence from left to right; and in the third row of each subarray, the third, first and second display units 330, 320 and 310 are arranged in sequence from left to right. It should be understood that the above-mentioned left-to-right direction is merely exemplary, and in other embodiments, the display units may be arranged from right to left, and the embodiments of the present disclosure have no limitation in this aspect.

In some embodiments, the first display unit 310 may emit red light, the second display unit 320 may emit green light, and the third display unit 330 may emit blue light, and thus the first row of the subarray forms an R/G/B arrangement, the second row of the subarray forms a G/B/R arrangement, and the third row of the subarray forms a B/R/G arrangement. In some other embodiments, the first display unit 310 may emit red light, the second display unit 320 may emit blue light, and the third display unit 330 may emit green light, and thus the first row of the subarray forms an R/B/G arrangement, the second row of the subarray forms a B/G/R arrangement, and the third row of the subarray forms a G/R/B arrangement. Similarly, in other embodiments, the first, second and third display units 310, 320 and 330 emitting one of red, green and blue lights may be arranged in other arrangements to obtain other color arrangements, and the embodiments of the present disclosure have no limitation in this aspect.

In the embodiments of the present disclosure, the problem of visual graininess at the edge when the display panel is cut into an irregular shape may be solved by arranging the first, second and third display units 310, 320 and 330 in the subarray in the above-mentioned order.

FIG. 4 is a sectional view along A-A′ line in FIG. 3. As shown in FIG. 4, a light blocking layer 302 is arranged on the base substrate 301. The light blocking layer 302 is located between adjacent display units, and configured for protecting the base substrate 301 and blocking the light rays emitted from a side surface of the color filter, and preventing crosstalk. For example, the light blocking layer 302 for example, may be made of a light blocking material, such as a metal layer, a metal oxide layer, a dark resin layer, or the like.

A driving circuit 303 for a display unit may also be formed on the base substrate 301. The Micro-LED chip is electrically connected with the driver circuit 303 through wire bonding, binding, or the like. The driver circuit 303 is configured for providing a driving voltage to the display unit so that the Micro-LED chip in the display unit may emit light. This driver circuit may be for example transistors, capacitors, or the like, and may include a switch transistor, a driver transistor and a storage capacitor (2T1C structure). The switch transistor is connected with a gate line and a data line, receives a data voltage signal from the data line under the control of a scan signal on the gate line, and then stores the data voltage signal in the storage capacitor and controls a conduction current of the driver transistor, thereby controlling a luminous intensity of the Micro-LED in the Micro-LED chip. In FIG. 4, the driver circuit 303 is shown by taking a thin film transistor as an example, and a gate of the thin film transistor is electrically connected with the gate line, a source of the thin film transistor is connected with the data line, and a source of the thin film transistor may be electrically connected with the Micro-LED chip in the corresponding display unit, thereby providing the data voltage signal provided by the data line to the Micro-LED chip under the control of the scan signal on the gate line, so as to drive the Micro-LED chip to emit light.

The base substrate 301 may be made of a material such as glass, ceramic, polyimide, silicon, or the like, and may be for example a single-layer substrate or a multi-layer substrate. In the case where the base substrate 301 is a silica-based substrate, the driver circuit 303 may be formed on the base substrate 301 through the semiconductor process conveniently, which simplifies the manufacturing process of the display substrate. In some embodiments, the Micro-LED chip and the color filter of the display unit of the display substrate are formed on the same base substrate. For example, in the embodiments shown in FIGS. 3 to 4, the base substrate 301 is used as the base substrate of each of the display units 310-330. That is, the display units of the display substrate 300 share the same base substrate 301. However, in another embodiment, the Micro-LED chips and the color filters of a part of the display units of the display substrate may be arranged on a base substrate, whereas the Micro-LED chips and the color filters of another part of the display units of the display substrate may be arranged on another base substrate, and the embodiments of the present disclosure have no limitation in this aspect.

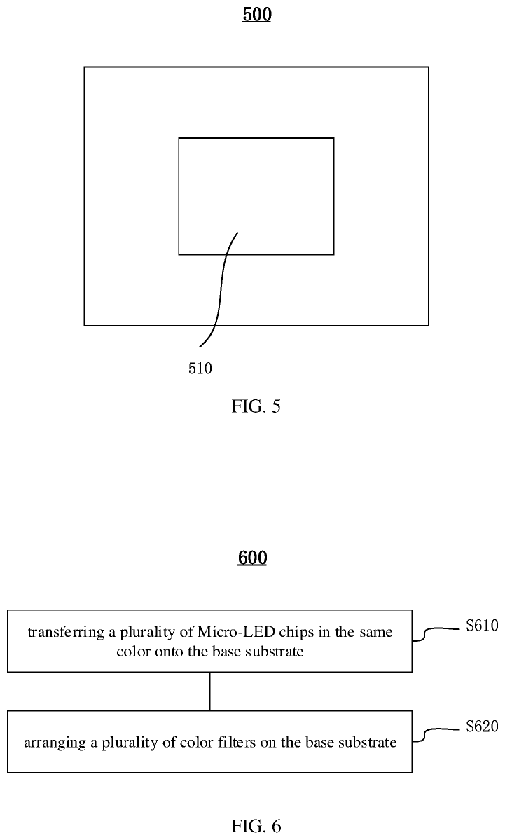

Some embodiments of the present disclosure further provide a display device, including the above-mentioned display substrate. As shown in FIG. 5, the display device 500 according to some embodiments of the present disclosure may include a display substrate 510. The display device 500, for example, may be a Micro-LED display, or a liquid crystal display, wherein the display substrate 510 is used as a backlight source of the display device 500, and the display device 500 may further include other elements, such as a liquid crystal layer. The display device 500 may be a display screen arranged in a virtual reality display device or an augmented reality display device. For example, the display screen has an irregular shape (such as ellipse) which is not rectangular, and is configured for receiving a display signal from a controller in the virtual reality display device or the augmented reality display device so as to display images.

Some embodiments of the present disclosure further provide a method of manufacturing the above-mentioned display substrate. As shown in FIG. 6, the method 600 of manufacturing the display substrate according to some embodiments of the present disclosure include steps S610 and S620.

In step S610, a plurality of Micro-LED chips in the same color are transferred onto the base substrate.

The Micro-LED chip is an unpackaged bare chip. In some embodiments, the Micro-LED chips may be transferred onto the base substrate through a micro-transfer technology. For example, separate Micro-LED chips are obtained by being manufactured and cut on a semiconductor base (such as a silicon base). In the micro-transfer technology, the transfer of the Micro-LED chip is finished by using a patterned transfer head, for example, a Polydimethylsiloxane (PDMS) transfer head with a convex structure to pick up the Micro-LED chip (that is, the bare chip) from the supply substrate through a PDMS transfer layer with adhesiveness, aligning the PDMS transfer head with a reception substrate, attaching the Micro-LED chip picked up by the PDMS transfer head onto a preset position of the reception substrate, and finally peeling the PDMS transfer head from the reception substrate.

In step S620, a plurality of color filters is arranged on the base substrate, wherein each color filter covers and packages at least one Micro-LED chip to obtain the display substrate.

For example, the color filter may be manufactured in advance, or may be manufactured on the base substrate after the Micro-LED chip is transferred to the base substrate, for example, through pressing, photoetching, or the like, and the embodiments of the present disclosure are not limited thereto. For example, when the color filter is made of colored glass cement or colored resin, the colored glass cement or colored resin which is not cured may be first applied onto the display substrate provided with the display unit, a microlens corresponding to the display unit is obtained by pressing the applied colored glass cement or colored resin, and then curing is performed to obtain the color filter with a required shape. The red, green and blue color filters may be manufactured in sequence. The obtained color filters not only serve to filter color and modulate light, but also achieve the function of packaging (sealing). As required, the color converting material may also be added in the colored glass cement or colored resin, for example, a fluorescent material, a quantum dot material, or the like, thereby converting incident white light into light in a preset color, and improving an optical purity and a luminous intensity of the color filter.

The descriptions about the Micro-LED chip, color filter, and base substrate mentioned in the method 600 may refer to the above-mentioned description related to FIGS. 1 to 4, and are not repeated herein.

In the method of manufacturing the display substrate according to the embodiments of the present disclosure, the Micro-LEDs emitting light in different colors may be prevented from being transferred to the base substrate in batches for many times, the difficulty and the accuracy requirement are reduced, and the product yield is improved.

The foregoing are merely exemplary embodiments of the disclosure, and not intended to define the scope of the disclosure, and the scope of the disclosure is determined by the appended claims.

What is claimed is:

1. A display unit, comprising:
a micro light emitting diode (Micro-LED) chip, arranged on a base substrate and configured for emitting light in a first color; and
a color filter, the color filter being arranged on the Micro-LED chip, the color filter being configured for packaging the Micro-LED chip and converting the light in the first color into an outgoing light in a second color, and the color filter comprising a convex structure in a light outgoing path of the Micro-LED chip.

2. The display unit according to claim 1, wherein the convex structure is a convex lens structure.

3. The display unit according to claim 2, wherein the Micro-LED chip is at a focal point of the convex lens, so as to convert the light in the first color emitted from the Micro-LED chip into the outgoing light in the second color, and the outgoing light in the second color is substantially parallel.

4. The display unit according to claim 2, wherein a distance from the micro-LED chip to an optical center of the convex lens is less than a focal length of the convex lens.

5. The display unit according to claim 1, wherein in at least one direction, the Micro-LED chip has a dimension in a range of 1 micron˜10 microns.

6. The display unit according to claim 1, wherein the first color is white, and the second color is one selected from a group consisting of red, blue and green.

7. A display substrate, comprising:
a base substrate; and
a plurality of display units, arranged on the base substrate in an array,
wherein each of the plurality of display units comprises:
a micro light emitting diode (Micro-LED) chip, arranged on a base substrate and configured for emitting light in a first color; and
a color filter, the color filter being arranged on the Micro-LED chip, the color filter being configured for packaging the Micro-LED chip and converting the light in the first color into an outgoing light in a second color, and the color filter comprising a convex structure in a light outgoing path of the Micro-LED chip, and
the plurality of display units are divided into a plurality of subarrays, each of the plurality of subarrays comprises a first display unit, a second display unit and a third display unit, the first display unit, the second display unit and the third display unit emit outgoing light in different colors.

8. The display substrate according to claim 7, wherein in each of the plurality of subarrays, each of the first display unit, the second display unit and the third display unit is arranged adjacent to a different type of display unit in each of a row direction and a column direction.

9. The display substrate according to claim 8, wherein each of the first display unit, the second display unit and the third display unit of each of the plurality of subarrays is arranged adjacent to a different type of display unit of an adjacent subarray in each of the row direction and the column direction.

10. The display substrate according to claim 9, wherein
the outgoing light emitted from each of the first display unit, the second display unit and the third display unit has a color of one selected from a group consisting of red, green and blue, and the outgoing light emitted from the first display unit, the second display unit and the third display unit has different colors.

11. The display substrate according to claim 10, wherein each of the plurality of subarrays comprises:
the first display unit, the second display unit and the third display unit arranged in sequence in a first direction in a first row;
the second display unit, the third display unit and the first display unit arranged in sequence in the first direction in a second row; and
the third display unit, the first display unit and the second display unit arranged in sequence in the first direction in a third row,
wherein the first display unit emits red outgoing light, the second display unit emits green outgoing light, and the third display unit emits blue outgoing light.

12. The display substrate according to claim 7, further comprising a light blocking layer, wherein the light blocking layer is on the base substrate and between adjacent display units.

13. A display device, comprising the display substrate according to claim 7.

14. A method of manufacturing the display substrate according to claim 7, comprising:
transferring a plurality of Micro-LED chips in an identical color onto the base substrate; and
arranging a plurality of color filters on the base substrate, wherein each of the plurality of color filters covers and packages at least one of the plurality of Micro-LED chips to obtain the display substrate.

15. The display unit according to claim 2, wherein the first color is white, and the second color is one selected from a group consisting of red, blue and green.

16. The display unit according to claim 3, wherein the first color is white, and the second color is one selected from a group consisting of red, blue and green.

17. The display unit according to claim 4, wherein the first color is white, and the second color is one selected from a group consisting of red, blue and green.

18. The display unit according to claim 5, wherein the first color is white, and the second color is one selected from a group consisting of red, blue and green.

19. The display substrate according to claim 7, wherein the convex structure is a convex lens structure.

20. The display substrate according to claim 7, wherein the Micro-LED chip is at a focal point of the convex lens, so as to convert the light in the first color emitted from the Micro-LED chip into the outgoing light in the second color, and
the outgoing light in the second color is substantially parallel.
